(19) United States
(12) Patent Application Publication
(10) Pub. No.: US 2026/0144076 A1
(43) Pub. Date: May 21, 2026

(54) Protective Dam on System-on-Chip Wafer Level Multi-Chip Module Package for EMI Shielding

(71) Applicant: Apple Inc., Cupertino, CA (US)

(72) Inventors: Seungjae Lee, San Jose, CA (US); Ninad Makarand Shahane, San Francisco, CA (US); Zhitao Cao, Campbell, CA (US); Chueh-An Hsieh, Hsinchu County (TW); Ying-Chieh Ke, Taoyuan (TW); Imran Hashim, Saratoga, CA (US); Wei Chen, San Jose, CA (US)

(21) Appl. No.: 18/955,544

(22) Filed: Nov. 21, 2024

(51) Int. Cl. H01L 23/552; H01L 21/56; H01L 23/538; H01L 25/16

(52) U.S. Cl. CPC H10W 42/20; H10W 70/611; H10W 70/685; H10W 74/01; H10W 90/00

(57) ABSTRACT

Integrated circuit (IC) structures and methods of assembly are described in which a protective damn structure is formed for EMI shielding. Further, an IC die is bonded to the top side of a routing layer and encapsulated with a gap fill material, where an EMI shielding layer is formed over the exposed surfaces of the IC die, routing layer and gap fill material. In an embodiment, a dam structure may be formed on the back side of the routing layer that surrounds an array of contact terminals on the back side of the routing layer. In embodiments, the height of the dam structure is less than the height of the array of contact terminals but greater than the thickness of the EMI shielding layer. In an embodiment, the routing layer includes a step, where the step has a height that is greater than the thickness of the EMI shielding layer.

### BACKGROUND

### Field

Embodiments described herein relate to semiconductor packaging, more particularly to shielding electromagnetic interference.

### Background Information

Electromagnetic interference (EMI) is unwanted interference in an electrical path or circuit. Such interference can distort signals, introduce noise and may ultimately cause the malfunction and/or failure of electronic devices, equipment, and systems used in critical applications. EMI shielding is crucial for protecting semiconductor packages from such electromagnetic disturbances and ensuring their reliability and functionality in increasingly compact and sensitive electronic devices. EMI shielding may be applied by various methods, such as sputtering, spraying, printing, plating, etc.

### SUMMARY

Embodiments describe integrated circuit (IC) structures and methods of assembly. In an embodiment, the IC structure includes an integrated circuit (IC) die bonded to the top side of a routing layer and encapsulated by a gap fill material, where an EMI shielding layer is formed over the exposed surfaces of the IC die, routing layer and gap fill material. In an embodiment, the IC structure includes a dam structure and an array of contact terminals on the back side of the routing layer, where the dam structure laterally surrounds the array of contact terminals. Further, the height of the dam structure may be less than the height of the array of contact terminals but greater than the thickness of the EMI shielding layer. In an embodiment, the IC structure includes a step that extends through a partial thickness of the routing layer from the back side of the routing layer to a step ceiling within the routing layer. Further, the height of the step may be greater than the thickness of the EMI shielding layer.

### BRIEF DESCRIPTION OF THE DRAWINGS

FIG. 1A is a schematic cross-sectional side view illustration of an integrated circuit (“IC”) structure that includes a dam structure in accordance with embodiments.

FIG. 1B is a schematic cross-sectional side view illustration of an IC structure that includes a dam structure with contact terminals in accordance with embodiments.

FIG. 1C is a schematic cross-sectional side view illustration of an IC structure that includes a dam structure mounted to a substrate in accordance with embodiments.

FIG. 2A is a schematic bottom view illustration of an IC structure that includes a continuous dam structure in accordance with embodiments.

FIG. 2B is a schematic bottom view illustration of an IC structure that includes a continuous dam structure with contact terminals in accordance with embodiments.

FIG. 2C is a schematic bottom view illustration of an IC structure that includes a continuous dam structure with staggered contact terminals in accordance with embodiments.

FIG. 3A is a schematic bottom view illustration of an IC structure that includes a non-continuous dam structure in accordance with embodiments.

FIG. 3B is a schematic bottom view illustration of an IC structure that includes a non-continuous dam structure with contact terminals in accordance with embodiments.

FIG. 3C is a schematic bottom view illustration of an IC structure that includes a non-continuous dam structure with staggered contact terminals in accordance with embodiments.

FIG. 4 is a flow chart of a method for assembling an IC structure that includes a dam structure in accordance with embodiments.

FIGS. 5A-5E are schematic cross-sectional side view illustrations for a method of assembling an IC structure that includes a dam structure in accordance with embodiments.

FIG. 6 is a schematic cross-sectional side view illustration of an IC structure that includes a step in accordance with embodiments.

### DETAILED DESCRIPTION

During the process of applying an EMI shielding layer to an integrated circuit (IC) package, the IC package may be mounted on an adhesive tape, where metal layers (e.g., stainless steel, copper, etc.) may then be sputtered onto the exposed surfaces of the IC package. However, during the sputtering process, the metal layers may not only be applied to the IC package but also to the adhesive tape on which the IC package is mounted. It has been observed that during conventional packaging techniques the metal layers on the IC package and the metal layers on the adhesive tape may become bridged or connected, where such a bridge or connection must be broken in order to remove the IC package from the adhesive tape after completion of the sputtering process. In some instances, the breaking of such a bridge or connection between the shielding layer on the IC package and the shielding layer on the adhesive tape may cause burring at the package edge. Further, conventional IC packages may include solder resist (also commonly referred to as a solder mask) on the back side of the IC package, and during the EMI shielding layer deposition process the solder resist can also be a contact surface with the adhesive tape. However, current IC packages may include a low-temperature polyimide rather than a traditional solder resist material on the back side of the IC package. It has additionally been observed that peeling or damage to such a polyimide surface can occur during removal of the IC package from the adhesive tape after completion of the EMI shielding layer deposition process.

In embodiments, an IC structure may include an integrated circuit (IC) die bonded to the top side of a routing layer and encapsulated by a gap fill material (e.g., epoxy molding compound, etc.), where an EMI shielding layer may be formed over the exposed surfaces of the IC die, routing layer and gap fill material. Further, the bottom side of the routing layer may include an array of contact terminals and a dam structure, where the dam structure surrounds the array of contact terminals and is located between the array of contact terminals and a lateral edge of the routing layer. In embodiments, the height of the dam structure may be less than the height of an array of contact terminals but greater than the thickness of the EMI shielding layer. In this way, the dam structure provides a gap between the back side of the routing layer and the adhesive tape of the mount so that the EMI shielding layer does not “bridge” from the IC structure to the adhesive tape, which may aid in mitigating or eliminating the risk of burring around the package edge as well as the risk of peeling or damage to the polyimide layer on the back side of the routing layer. In another embodiment, the IC structure may include a step rather than a dam structure to prevent bridging of the EMI shielding layer from the IC structure to the adhesive tape during the sputtering process. In such instances, the step may extend through a partial thickness of the routing layer from the back side of the routing layer to a step ceiling within the routing layer, where the height of the step may be greater than the thickness of the EMI shielding layer.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “over”, “to”, “between”, “spanning” and “on” as used herein may refer to a relative position of one layer with respect to other layers. One layer “over”, “spanning” or “on” another layer or bonded “to” or in “contact” with another layer may be directly in contact with the other layer or may have one or more intervening layers. One layer “between” layers may be directly in contact with the layers or may have one or more intervening layers.

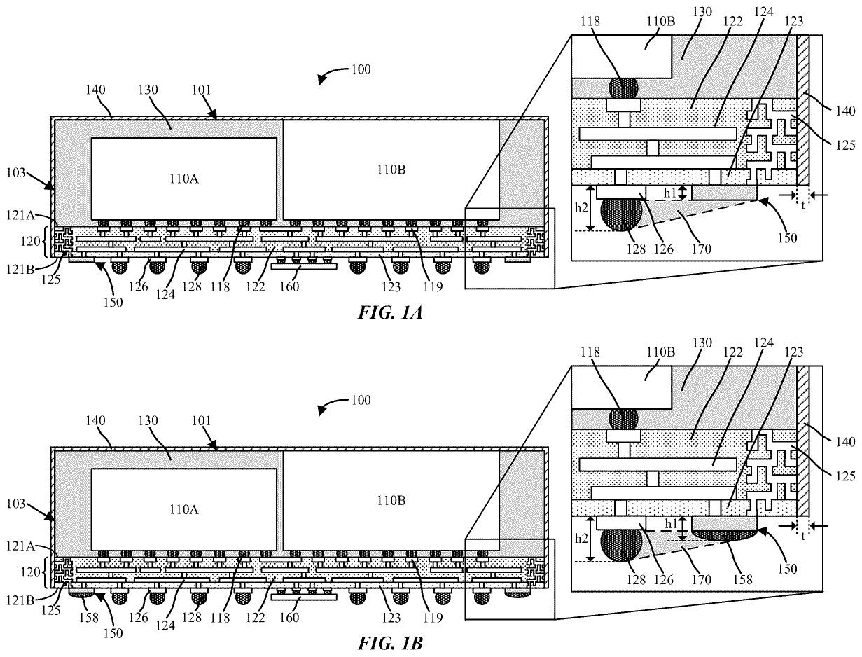

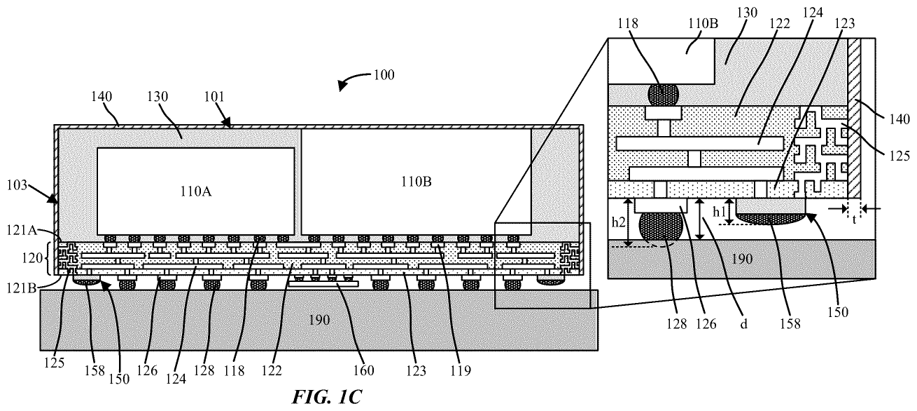

Referring now to FIGS. 1A-1B, FIG. 1A is a schematic cross-sectional side view illustration of an integrated circuit (“IC”) structure 100 that includes a dam structure in accordance with embodiments, FIG. 1B is a schematic cross-sectional side view illustration of an IC structure 100 that includes a dam structure with contact terminals in accordance with embodiments. IC structure 100 may be a wafer level multi-chip module in which multiple IC dies (e.g., system-on-chip (SOC), dynamic random-access memory (DRAM), etc.) are bonded to a routing layer and encapsulated by a gap fill material. In some embodiments the gap fill material may include a molding compound (e.g., epoxy molding compound, etc.) to encapsulate the IC dies, whereas in other embodiments the gap fill material may include other suitable material that may be deposited rather than molded (e.g., oxides, silicon, etc.) to encapsulate the IC dies. In the example of FIGS. 1A-1B, dies 110A and 110B are bonded to routing layer 120 and encapsulated by gap fill material 130. In some embodiments, IC structure 100 may be packaged according to a “chip first” approach in which the IC dies are diced and encapsulated within a gap fill material to form a reconstituted wafer or panel, where a redistribution layer is then formed on the reconstituted wafer followed by singulation of the IC dies. In other embodiments, IC structure 100 may be packaged according to a “chip last” approach in which the IC dies are bumped and bonded to an existing redistribution layer, encapsulated with a gap fill material and then singulated. Further, the IC dies 110A, 110B may be bonded to contact pads 119 of routing layer 120 by contact terminals 118 (e.g., solder bumps) of IC dies 110A, 110B as illustrated in FIGS. 1A-1B (e.g., flip chip bonding) where such embodiments may include an optional underfill between the IC dies and routing layer (not illustrated), although other bonding methods are contemplated (e.g., hybrid bonding, etc.).

In further reference to FIGS. 1A-1B, routing layer 120 may be formed by a layer-by-layer process, and may be formed using thin film technology. For example, as described above, routing layer 120 may be formed on a reconstituted wafer or panel that includes diced/encapsulated dies in accordance with a chip first approach, or on a carrier substrate, for example, where the dies may be bumped and bonded to routing layer 120 in accordance with a chip last approach. Further, routing layer 120 may also include one or more redistribution lines 124 and one or more dielectric layers 122. The one or more dielectric layers may be formed by standard deposition techniques (e.g., lamination, spin coating, spray coating, physical vapor deposition, chemical vapor deposition, etc.) and may include suitable materials to provide features such as isolating interconnect levels, stress buffering, etc. Further, routing layer 120 may include a passivation layer, such as passivation layer 123 (e.g., low temperature polyimide (“LTPI”), etc.) on back side 121B of routing layer 120. The redistribution lines 124 may be embedded (e.g., embedded traces) in the dielectric layer(s) 122, and may include, but are not limited to, metallic materials such as copper, titanium, nickel, gold, and combinations or alloys thereof. Further, redistribution lines 124 may also include contact pads 119 to connect to other devices. For example, IC dies (e.g., 110A, 110B, etc.) may be bonded (e.g., flip chip bonded, hybrid bonded, etc.) to top side 121A of routing layer 120, and integrated passive devices (e.g., inductors, capacitors, resistors, couplers, filters, and power combiners/dividers, etc.), such as integrated passive device 160 in FIGS. 1A-1B, may be bonded to back side 121B of routing layer 120. Back side 121B of routing layer 120 may also include contact terminals 128 (e.g., solder bumps, pillars, sockets, planar contact pads, etc.) formed on under bump metallization (UBM) pads 126.

Still referring to FIGS. 1A-1B, IC structure 100 may also include an electromagnetic interference (EMI) shielding layer 140. EMI shielding layer 140 may be formed by any suitable method (e.g., sputtering, spraying, etc.) and may include any suitable material to protect devices or signals from electromagnetic interference, such as copper, stainless steel, aluminum, etc. or any composites or combinations thereof. In an embodiment, EMI shielding layer 140 may include sputtered stainless steel-copper-stainless steel layers. Further, EMI shielding layer 140 may cover any exposed surfaces of IC structure 100. For example, EMI shielding layer 140 may cover top surface 101 and lateral edges 103. In the examples of FIGS. 1A-1B, top surface 101 includes the exposed surfaces of gap fill material 130 and IC die 110B. It should be noted that the top surfaces of the IC dies may be exposed by a backgrinding operation after molding or gap fill, where the gap fill material still encapsulates the IC dies after such a backgrinding operation. In further reference to the examples of FIGS. 1A-1B, lateral edges 103 includes the exposed surfaces of gap fill material 130 and routing layer 120. In some embodiments, lateral edges 103 may also include the diced edge of at least one of the multiple IC dies bonded to routing layer 120 where singulation occurs through an IC die. Further, EMI shielding layer 140 may also contact seal ring 125, which is connected to ground and in turn connects EMI shielding layer 140 to ground.

It has been observed that during the process of forming the EMI shielding layer (e.g., sputtering), the EMI shielding layer may not only be formed on the IC structure itself but also on the adhesive tape on which the IC structure is mounted. In some instances, the EMI shielding layer forms as a continuous/unbroken layer from the IC structure to the adhesive tape. In such instances, during unloading/detaching of the IC structure from the adhesive tape, the continuous/unbroken layer must be broken, where the breaking of such a layer may cause burring at the package edge. Further, during unloading/detaching of the IC structure from the adhesive tape, the adhesive tape may also cause the passivation layer on the bottom surface of the routing layer (e.g., passivation layer 123) to peel or delaminate. As such, in embodiments IC structure 100 may include dam structure 150 to prevent the formation of a continuous/unbroken EMI shielding layer from the IC structure to the adhesive tape, and prevent the dielectric layer from directly contacting the adhesive tape during the formation process.

In further reference to FIGS. 1A-1B, IC structure 100 may include dam structure 150. Dam structure 150 may be any suitable material, such as metal-based material (e.g., copper, solder, metal pastes, etc.), organic material (e.g., polyimides, solder resist, etc.), or any combination thereof. Further, dam structure 150 may be formed on back side 121B of routing layer 120 by any suitable method and may take a variety of shapes (e.g., bars, pads, bumps, pillars, sockets, etc.). For example, in embodiments where dam structure 150 includes organic material (e.g., polyimide, etc.), an organic dam structure may be formed by standard deposition techniques and patterned to form any shape (e.g., bars, pads, etc.). In embodiments where dam structure 150 includes metal-based material (e.g., copper, solder, etc.), a UBM dam structure may be formed by standard techniques (e.g., sputtering) as illustrated in the example of FIG. 1A, or a solder dam structure may be formed by standard techniques (e.g., printing, plating, etc.) as illustrated in the example of FIG. 1B, although embodiments are not so limited and it is understood other dam structures are contemplated (e.g., bars, pillars, sockets, etc.). In other embodiments still, the UBM dam structure may be formed by metal-based material and organic material together.

In such embodiments, the height of the dam structure may be less than the height of the array of contact terminals but greater than the thickness of the EMI shielding layer. For example, in the embodiment illustrated in FIG. 1A, the height, h1, of dam structure 150 is less than the height, h2, of the array of contact terminals 128, but greater than the thickness, t, of EMI shielding layer 140. In the example illustrated in FIG. 1B, the height, h1, of the dam structure 150 is less than the height, h2, of the array of contact terminals 128 but greater than the thickness, t, of EMI shielding layer 140, where h1 includes the height of contact terminal 158 (e.g., solder bump) on dam structure 150. Further, dam structure 150 may create a lateral shadow on the interior region of IC structure 100 between dam structure 150 and the array of contact terminals 128, such as lateral shadow 170 in FIGS. 1A-1B, where such lateral shadows may obscure at least a portion of the array of contact terminals 128. In this way, the dam structure can protect the array of contact terminals from contamination during the sputtering process. In addition, dam structure 150 may connect to EMI shielding layer 140 through seal ring 125, where all such components are connected to ground.

Referring now to FIG. 1C, a schematic cross-sectional side view illustration is shown of an IC structure that includes a dam structure mounted to a substrate in accordance with embodiments. The embodiment described in FIG. 1C is substantially similar to the embodiments described in FIGS. 1A-1B except the embodiment described in FIG. 1C represents IC structure 100 after package mount, whereas the embodiments described in FIGS. 1A-1B represent IC structure 100 before package mount. For example, in the embodiments described in FIGS. 1A-1B, the height, h2, of the array of contact terminals 128 relates to the distance from back side 121B of routing layer 120 to contact terminal 128 before reflow. During package mount of IC structure 100 to a substrate, such as substrate 190 in FIG. 1C, reflow of the array contact terminals 128 may cause the standoff distance, d, between back side 121B of routing layer 120 and the substrate to be less than h2. Such tolerances before and after reflow can be a factor in determining the height of dam structure 150 so as to prevent the dam structure from contacting the substrate during package mount. In addition, where dam structure 150 is a solder dam structure as illustrated in FIG. 1B, the solder material may be a higher temperature solder than that of contact terminal 128 so as to prevent reflow of the solder dam structure during package mount.

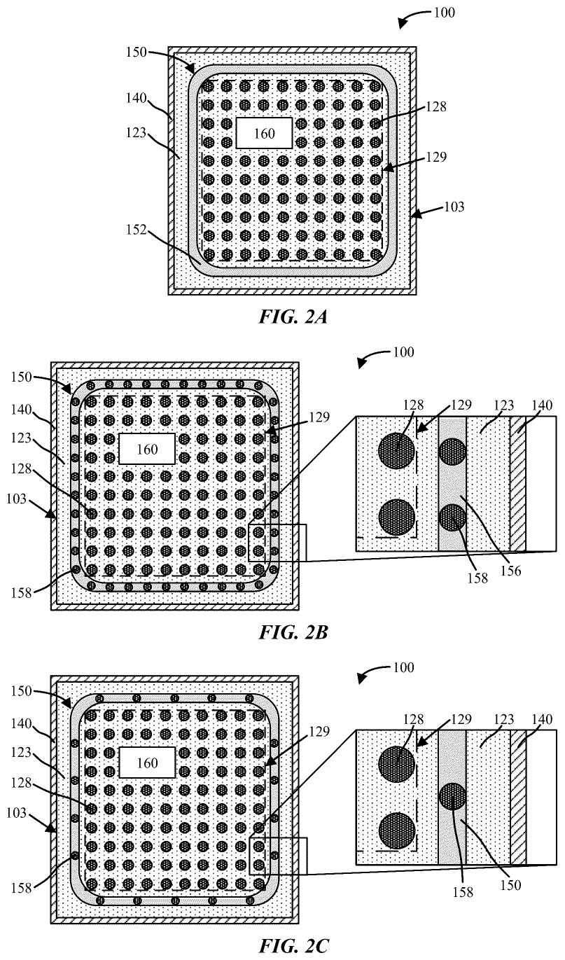

Referring now to FIG. 2A-2C, FIG. 2A is a schematic bottom view illustration of an IC structure that includes a continuous dam structure in accordance with embodiments, FIG. 2B is a schematic bottom view illustration of an IC structure that includes a continuous dam structure with contact terminals in accordance with embodiments, FIG. 2C is a schematic bottom view illustration of an IC structure that includes a continuous dam structure with staggered contact terminals in accordance with embodiments. As illustrated in FIGS. 2A-2C, dam structure 150 may be formed on passivation layer 123 and may be continuous. Further, dam structure 150 may laterally surround the array of contact terminals 128 and may be located between a periphery 129 of the array of contact terminals 128 and lateral edge 103. In an embodiment, dam structure 150 may include chamfered corners, such as chamfer corners 152. In some embodiments, dam structure 150 may include contact terminals (e.g., micro solder bumps, etc.), such as contact terminals 158 illustrated in FIGS. 2B-2C. In such embodiments, the contact terminals on the dam structure may be either laterally adjacent or staggered with respect to the corresponding contact terminals in the array of contact terminals. For example, as illustrated in FIG. 2B, contact terminal 158 on dam structure 150 is laterally adjacent to contact terminal 128 of the array of contact terminals. Alternatively, as illustrated in FIG. 2C, contact terminal 158 on dam structure 150 is staggered from contact terminal 128 of the array of contact terminals so as to align with the space between the contact terminals of the array of contact terminals 128.

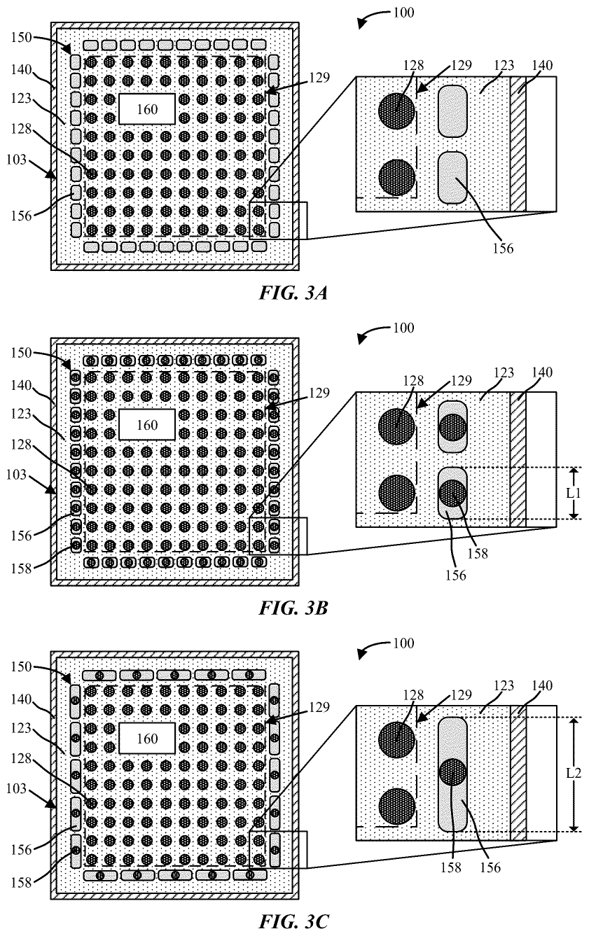

Referring now to FIG. 3A-3C, FIG. 3A is a schematic bottom view illustration of an IC structure that includes a non-continuous dam structure in accordance with embodiments, FIG. 3B is a schematic bottom view illustration of an IC structure that includes a non-continuous dam structure with contact terminals in accordance with embodiments, FIG. 3C is a schematic bottom view illustration of an IC structure that includes a non-continuous dam structure with staggered contact terminals in accordance with embodiments. As illustrated in FIGS. 3A-3C, dam structure 150 may be formed on passivation layer 123 and may be non-continuous in that dam structure 150 may be “broken up” into individual segments, such as segment 156. Further, dam structure 150 may laterally surround the array of contact terminals 128 and is located between a periphery 129 of the array of contact terminals 128 and lateral edge 103. In some embodiments, dam structure 150 may include contact terminals (e.g., micro solder bumps, etc.), such as contact terminals 158 illustrated in FIGS. 3B-3C. In such embodiments, the contact terminals on the dam structure may be either laterally adjacent or staggered with respect to the corresponding contact terminals in the array of contact terminals. For example, as illustrated in FIG. 3B, contact terminal 158 on segment 156 of dam structure 150 is laterally adjacent to contact terminal 128 of the array of contact terminals. Alternatively, as illustrated in FIG. 3C, contact terminal 158 on segment 156 of dam structure 150 is staggered with respect to contact terminal 128 of the array of contact terminals so as to align with the space between the corresponding contact terminals of the array of contact terminals 128. In addition, the length of each segment of the non-continuous dam structure may vary. For example, the length, L1, of segment 156 of dam structure 150 in FIG. 3B spans a single corresponding contact terminal (e.g., contact terminal 128) in the array of contact terminals, whereas the length, L2, of segment 156 of dam structure 150 in FIG. 3C spans multiple corresponding contact terminals in the array of contact terminals.

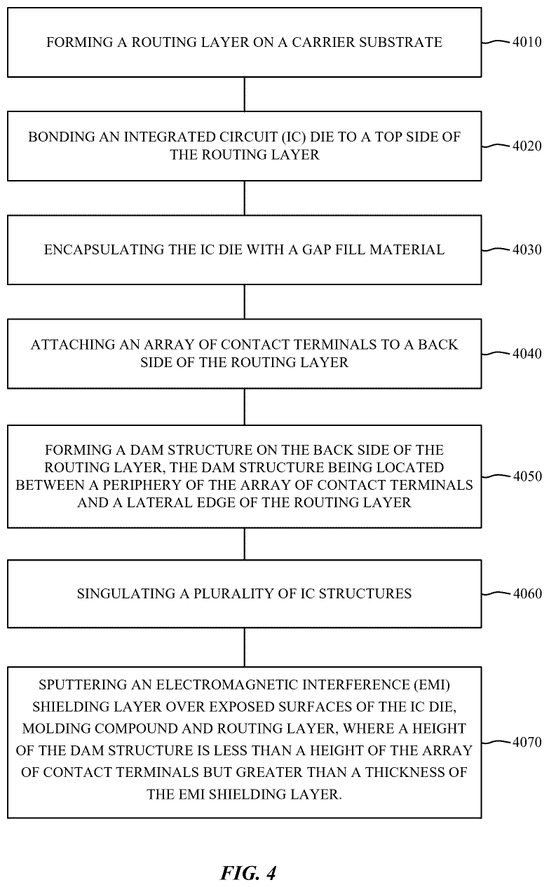

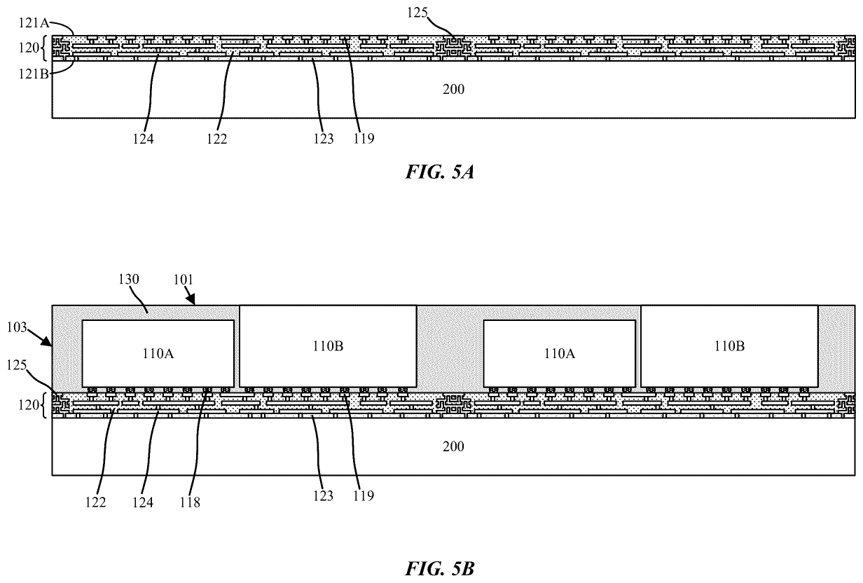

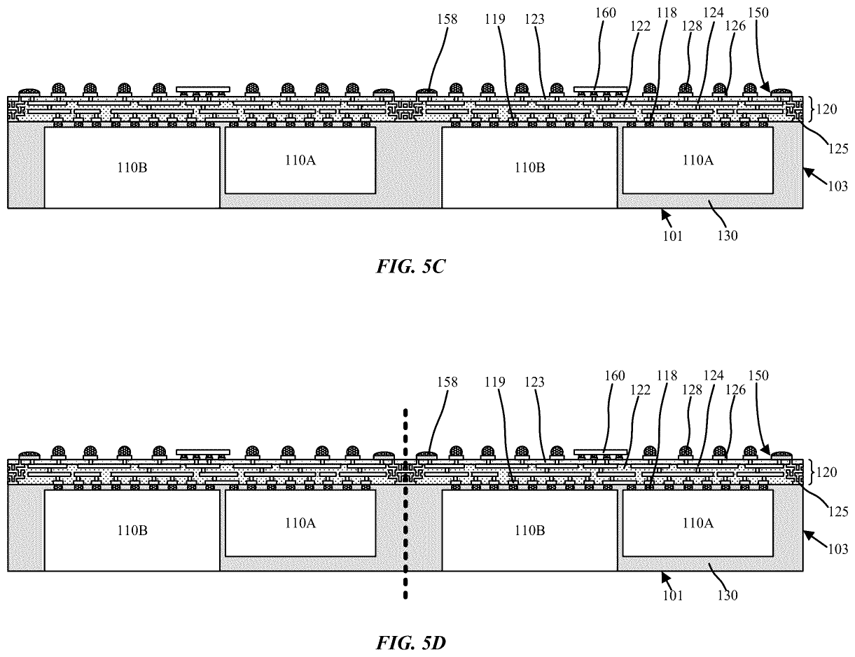

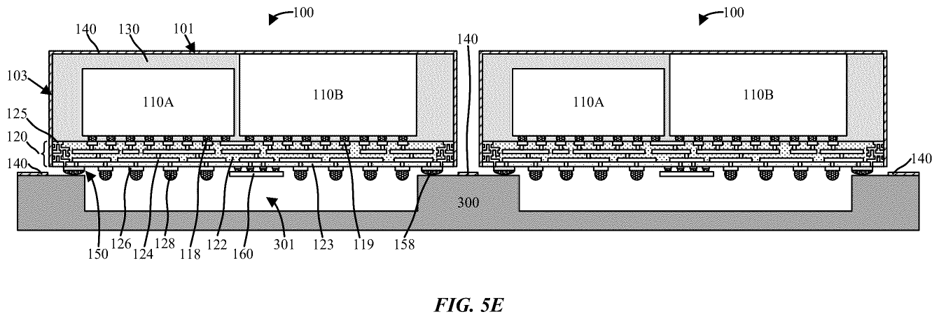

Referring now to FIG. 4 and FIGS. 5A-5E, FIG. 4 is a flow chart and FIGS. 5A-5E are schematic cross-sectional side view illustrations of a method for assembling an IC structure that includes a dam structure in accordance with embodiments. In the interest of clarity and conciseness, the method of FIG. 4 is described concurrently with the illustrations of FIGS. 5A-5E. It should be noted that the method described in FIG. 4 and FIGS. 5A-5E represents one approach of assembling IC structure 100 (e.g., chip last), and it is understood that other approaches of assembling IC structure 100 are contemplated (e.g., chip first, etc.). At operation 4010, FIG. 5A shows routing layer 120 formed on carrier substrate 200. The routing layer 120 may include one or more redistribution lines 124 (e.g., metal traces) embedded in one or more dielectric layers 122, where the back side 121B of routing layer 120 may include passivation layer 123 (e.g., low-temperature polyimide, etc.). At operation 4020, FIG. 5B shows IC dies 110A and 110B surface mounted to top side 121A of routing layer 120. In the embodiment illustrated in FIG. 5B, contact terminals 118 of IC dies 110A, 110B are bonded to contact pads 119 of routing layer 120 on top side 121A (e.g., flip chip bonding). In other embodiments, the IC dies may be bonded to the rounding layer by other suitable methods (e.g., hybrid bonding, etc.). In further reference to FIG. 5B, IC dies 110A, 110B may be encapsulated by gap fill material 130 at operation 4030. At operation 4040, FIG. 5C shows the array of contact terminals 128 (e.g., solder bumps) attached to back side 121B of routing layer 120.

In further reference to FIG. 5C, dam structure 150 may be formed on back side 121B of routing layer 120 at operation 4050. The dam structure 150 may be continuous as illustrated in the examples of FIGS. 2A-2C, or non-continuous as illustrated in the examples of FIGS. 3A-3C. In such embodiments, the height of dam structure 150 may be less than the height of the array of contact terminal 128 so that the array of contact terminals 128 may contact a substrate (and so that dam structure 150 does not contact a substrate) during package mount. Further, dam structure 150 may surround the array of contact terminals 128 and may be located between a periphery of the array of contact terminals 128 and lateral edge 103. In some embodiments, dam structure 150 may include organic material (e.g., polyimides, solder resist, etc.), which may be patterned to form a continuous dam structure as illustrated in FIG. 2A (e.g., polyimide bar), or a non-continuous dam structure as illustrated in FIG. 3A (e.g., polyimide segments). In other embodiments, dam structure 150 may include metal-based material (e.g., copper, solder, metal pastes, etc.), where standard techniques (e.g., sputtering, printing, plating, etc.) may be utilized to form a continuous dam structure as illustrated in FIG. 2A (e.g., metal bar), or a non-continuous dam structure as illustrated in FIG. 3A (e.g., UBM dam structure). In such metal-based embodiments, dam structure 150 may also include contact terminals 158 (e.g., solder bumps) to form a solder dam structure, where contact terminals 158 on the dam structure 150 may be adjacent to corresponding contact terminals in the array of contact terminals 128 as illustrated in FIG. 2B and FIG. 3B, or staggered between corresponding contact terminals in the array of contact terminals 128 as illustrated in FIG. 2C and FIG. 3C.

Referring now to FIG. 5D, IC structure 100 may be singulated to form a plurality of IC structures at operation 4060. In some embodiments, singulation may occur though gap fill material 130 and seal ring 125 of routing layer 120 so that lateral edge 103 of IC structure 100 includes gap fill material 130 and routing layer 120, as illustrated in FIG. 5D. In other embodiments, singulation may occur though the IC die so that lateral edge 103 of IC structure 100 may include gap fill material 130, routing layer 120, and IC die 110. At operation 4070, FIG. 5E shows EMI shielding layer 140 formed (e.g., sputtered, etc.) over the exposed surfaces of IC structure 100, such as top surface 101 (e.g., IC die 110B, gap fill material 130 etc.) and lateral edges 103 (e.g., routing layer 120, gap fill material 130, etc.). In such instances, dam structure 150 connects to EMI shielding layer 140 through seal ring 125, where all such components are connected to ground. In addition, EMI shielding layer 140 has a thickness, t, as illustrated in FIGS. 1A-1B. Referring back to FIG. 5C, when forming dam structure 150 on back side 121B of routing layer 120, the height, h1, of dam structure 150 may be less than the height, h2, of the array of contact terminals 128, and greater than the thickness, t, of EMI shielding layer 140. For example, before the forming (e.g., sputtering) of EMI shielding layer 140, IC structure 100 may be mounted on adhesive tape, such as adhesive tape 300 in FIG. 5E, where adhesive tape 300 includes cavity 301 so that the array of contact terminals 128 does not contact adhesive tape 300. Further, during sputtering, EMI shielding layer 140 may not only form on the exposed surfaces of IC structure 100, but may also form on adhesive tape 300 as illustrated in FIG. 5E. As such, the height of dam structure 150 should be greater than the thickness of EMI shielding layer 140 so that the shielding layer formed on IC structure 100 does not contact the shielding layer formed on adhesive tape 300. In this way, since the EMI shielding layer on IC structure 100 does not connect to the shielding layer formed on the adhesive tape, the risk of burring that may occur during removal of IC structure 100 from adhesive tape may be substantially reduced or eliminated.

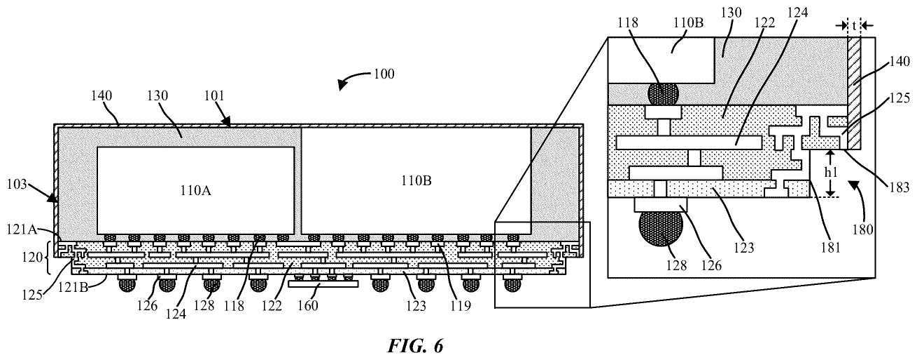

Referring now to FIG. 6, a schematic cross-sectional side view illustration is shown of an IC structure that includes a step in accordance with embodiments. The embodiment described in FIG. 6 is substantially similar to the embodiments described in FIGS. 1A-1B except FIG. 6 includes a step rather than a dam structure. For example, as shown in FIG. 6, IC structure 100 includes step 180 to prevent the formation of a bridge or connection between the shielding layer formed on the IC structure and the shielding layer formed on the adhesive tape during the sputtering process. Step 180 may be formed by any suitable method (e.g., etching, patterning, etc.) and may include step edge 181 and step ceiling 183. Further, step 180 may extend through a partial thickness of routing layer 120, where step 180 has a height, h1, that extends from back side 121B of routing layer 120 to step ceiling 183 located within routing layer 120. In such instances, the height, h1, of step 180 may be greater than the thickness, t, of EMI shielding layer 140. Further, the embodiment described may be used for flip chip bonding an IC structure to a substrate (e.g., printed circuit board, etc.) where the array of contact terminals 128 are solder bumps as illustrated in FIG. 6. It should be noted that the embodiment described may also be used for direct bonding (e.g., hybrid bonding, etc.) an IC structure to a substrate where the array of contact terminals 128 are planar contact pads, for example. In addition, one benefit of the embodiment described is that step 180 is a subtractive feature that preserves the planar surface needed for hybrid bonding the IC structure to a substrate. Conversely, the dam structure described in FIGS. 1A-1B is an additive feature that must ultimately be removed after formation of the EMI shielding layer to achieve the planar surface needed for hybrid bonding the IC structure to a substrate.

In utilizing the various aspects of the embodiments, it would become apparent to one skilled in the art that combinations or variations of the above embodiments are possible for forming a protective dam structure for EMI shielding. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. An integrated circuit (IC) structure comprising:
an integrated circuit (IC) die;
a routing layer including a top side and a back side, wherein the IC die is bonded to the top side, and the back side includes an array of contact terminals;
a gap fill material that encapsulates the IC die;
an electromagnetic interference (EMI) shielding layer formed over exposed surfaces of the IC die, the gap fill material and the routing layer; and
a dam structure formed on the back side of the routing layer, wherein a height of the dam structure is less than a height of the array of contact terminals but greater than a thickness of the EMI shielding layer.

2. The IC structure of claim 1, wherein the dam structure laterally surrounds the array of contact terminals and is located between a periphery of the array of contact terminals and a lateral edge of the routing layer.

3. The IC structure of claim 1, wherein the gap fill material is epoxy molding compound, and the array of contact terminals is solder bumps.

4. The IC structure of claim 1, wherein the dam structure includes organic material.

5. The IC structure of claim 1, wherein the dam structure includes metal-based material.

6. The IC structure of claim 1, wherein the dam structure is a continuous dam structure.

7. The IC structure of claim 6, wherein the continuous dam structure includes chamfered corners.

8. The IC structure of claim 1, wherein the dam structure is a non-continuous dam structure.

9. The IC structure of claim 8, wherein a segment of the non-continuous dam structure has a length that spans a corresponding contact terminal in the array of contact terminals.

10. The IC structure of claim 8, wherein a segment of the non-continuous dam structure has a length that spans multiple contact terminals in the array of contact terminals.

11. The IC structure of claim 1, wherein the dam structure includes contact terminals.

12. The IC structure of claim 11, wherein the contact terminals of the dam structure are laterally adjacent to corresponding contact terminals in the array of contact terminals.

13. The IC structure of claim 11, wherein the contact terminals of the dam structure are staggered between corresponding contact terminals in the array of contact terminals.

14. The IC structure of claim 1, wherein the back side of the routing layer includes a low-temperature polyimide layer.

15. The IC structure of claim 1, wherein the routing layer includes a seal ring, the seal ring being connected to the dam structure.

16. The IC structure of claim 1, further including an integrated passive device bonded to the back side of the routing layer.

17. The IC structure of claim 1, wherein the dam structure includes a lateral shadow on an interior region between the dam structure and the array of contact terminals, the lateral shadow obscuring at least a portion of the array of contact terminals.

18. A method for assembling an integrated circuit (IC) structure comprising:
forming a routing layer on a carrier substrate;
bonding an integrated circuit (IC) die to a top side of the routing layer;
encapsulating the IC die with a gap fill material;
attaching an array of contact terminals to a back side of the routing layer;
forming a dam structure on the back side of the routing layer, the dam structure being located between a periphery of the array of contact terminals and a lateral edge of the routing layer;
singulating a plurality of IC structures; and
sputtering an electromagnetic interference (EMI) shielding layer over exposed surfaces of the IC die, the gap fill material and the routing layer, wherein a height of the dam structure is less than a height of the array of contact terminals but greater than a thickness of the EMI shielding layer.

19. The method of claim 18, wherein the dam structure is a continuous dam structure.

20. The method of claim 18, wherein the dam structure is a non-continuous dam structure.

21. An IC structure comprising:
an IC die;
a routing layer including a top side and a back side, wherein the IC die is bonded to the top side, and the back side includes an array of contact terminals;
a gap fill material that encapsulates the IC die; and
an EMI shielding layer formed over exposed surfaces of the IC die, the gap fill material and the routing layer;
wherein the routing layer includes a step, the step having a height that is greater than a thickness of the EMI shielding layer.

22. The IC structure of claim 21, wherein the array of contact terminals is solder bumps.

23. The IC structure of claim 21, wherein the array of contact terminals is planar contact pads.

24. The IC structure of claim 21, wherein the height of the step extends through a partial thickness of the routing layer from the back side of the routing layer to a step ceiling within the routing layer.
